(19) United States
(12) Patent Application Publication
(10) Pub. No.: US 2010/0254486 A1
(43) Pub. Date: Oct. 7, 2010

(54) METHOD OF BLOCK-CODED GROUP MODULATION AND TRANSMITTER USING THE SAME

(75) Inventors: Mi Kyung OH, Gyeongju-si (KR); Hyung Soo LEE, Daejeon (KR); Jaehwan KIM, Daejeon (KR); Cheolhyo LEE, Daejeon (KR); Jung-yeol OH, Daejeon (KR); Hong Soon NAM, Daejeon (KR); Jae Young KIM, Daejeon (KR)

Correspondence Address: LADAS & PARRY LLP, 224 SOUTH MICHIGAN AVENUE, SUITE 1600, CHICAGO, IL, 60604, US

(73) Assignee: ELECTRONICS AND TELECOMMUNICATIONS RESEARCH INSTITUTE, Daejeon (KR)

(21) Appl. No.: 12/755,848

(22) Filed: Apr. 7, 2010

(30) Foreign Application Priority Data
Apr. 7, 2009 (KR) 10-2009-0029929
Jun. 3, 2009 (KR) 10-2009-0049242
Apr. 7, 2010 (KR) 10-2010-0031660

(51) Int. Cl. H04L 27/00; H03M 5/00

(52) U.S. Cl. 375/295; 341/55

(57) ABSTRACT

A transmitter using a method of block code-based group modulation includes a grouping unit, a generating unit, and a mapping unit. The grouping unit generates symbols by grouping a data bit stream into N-bit groups, and the generating unit generates a codeword set composed of codewords corresponding to combinations of arrangements of pulses that are generated by a result of grouping to a predetermined number. Next, the mapping unit block-maps a codeword selected from the codeword set to groups constituting the symbols.

### CROSS-REFERENCE TO RELATED APPLICATION

This application claims priority to and the benefit of Korean Patent Application Nos. 10-2009-0029929, 10-2009-0049242, and 10-2010-0031660 filed in the Korean Intellectual Property Office on Apr. 7, 2009, Jun. 3, 2009, and Apr. 7, 2010, respectively, the entire contents of which are incorporated herein by reference.

### BACKGROUND OF THE INVENTION

(a) Field of the Invention

The present invention relates to a method of group modulation and a transmitter using the same. In particular, the present invention relates to a method of block code-based group modulation and a transmitter using the method.

(b) Description of the Related Art

The impulse radio ultra-wideband (IR-UWB) wireless technology consumes a small amount of electrical power and does not interfere with other systems, such that it has been spotlighted as a next technology for a physical layer of the international standard IEEE 802.15.6 for on-body communication of a wireless body area network (WBAN).

The WBAN on-body communication should have an expanded data rate between about 10 Kbps and 10 Mbps at 3 m from a body. In order to implement reliable data communication in a wireless environment using an impulse, channel coding that detects and corrects errors that may be generated in wireless communication is required. However, the channel coding causes data throughput to decrease, such that it is difficult to implement a transmitting terminal having the maximum 100 Mbps data rate in a wireless communication network, such as the WBAN.

The above information disclosed in this Background period is only for enhancement of understanding of the background of the invention and therefore it may contain information that does not form the prior art that is already known in this country to a person of ordinary skill in the art.

### SUMMARY OF THE INVENTION

The present invention has been made in an effort to provide a method of group modulation having advantages of making it possible to correct errors without decreasing throughput in data communication in a wireless communication system, and a transmitter using the method.

An exemplary embodiment of the present invention provides a method of group modulation that includes: in a method of data modulation, generating symbols by grouping a data bit stream into N-bit groups; generating symbols by grouping an input data bit stream into N-bit groups; converting the symbols generated by the grouping to predetermined sequences; and converting the sequences to signal positions of a predetermined number.

Another embodiment of the present invention provides a method of group modulation that includes: generating symbols by grouping a data bit stream into N-bit groups; generating a block codeword set constituted by a plurality of codewords while corresponds to the result of grouping to the predetermined number; selecting candidate codewords of a predetermined number on the basis of the block codeword set; generating a final candidate codeword set by rearranging the selected candidate codewords; and block-mapping each of the groups constituting the symbols to one of the rearranged candidate codewords of the final candidate codeword set.

Yet another embodiment of the present invention provides a transmitter using a method of block code-based group modulation that includes: a grouping unit that generates symbols by grouping a data bit stream into N-bit groups; a generating unit that generates a codeword set composed of codewords corresponding to combinations of arrangements of pulses that are generated by the result of grouping to the predetermined number and generates a final candidate codeword set including 2^{N} candidate codewords in the codeword set; and a mapping unit that block-maps each of the groups constituting the symbols to one of the codewords of the final candidate codeword set.

### BRIEF DESCRIPTION OF THE DRAWINGS

FIG. 1 is a diagram illustrating a typical method of pulse position modulation.

FIG. 2 is a view illustrating a method of group modulation according to an exemplary embodiment of the present invention.

FIG. 3 is a diagram illustrating the number of cases of codeword sets that can be generated in a method of group modulation according to an exemplary embodiment of the present invention.

FIG. 4 is a diagram illustrating a codeword set selected from FIG. 3 to map bits in a method of group pulse position modulation according to an exemplary embodiment of the present invention.

FIG. 5 is a flowchart illustrating a method of group modulation according to an exemplary embodiment of the present invention.

FIG. 6 is a flowchart illustrating a method of selecting a codeword in a method of group modulation according to an exemplary embodiment of the present invention.

FIG. 7 is a block diagram illustrating a transmitter and a receiver according to an exemplary embodiment of the present invention.

FIG. 8 is a diagram comparing the performance of a PPM method, a GPPM method, and an OOK modulation method in a transmitter and a receiver according to an exemplary embodiment of the present invention.

FIG. 9 is a diagram comparing the performance of a PPM method and a GPPM method in a transmitter and a receiver according to an exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In the specification, unless explicitly described to the contrary, the word “comprise” and variations such as “comprises” or “comprising” will be understood to imply the inclusion of stated elements but not the exclusion of any other elements.

A method of group modulation according to an exemplary embodiment of the present invention and a transmitter using the method are described in detail with reference to the accompanying drawings.

In general, the most primary issue in an ultrawideband (UWB) system is in that how low power/low complexity the system can be configured in comparison with the existing wireless system. When a UWB signal is received in a coherent scheme, the low power/low complexity cannot be implemented. Therefore, a non-coherent receiver based on a non-coherent modulation method and energy detection is considered.

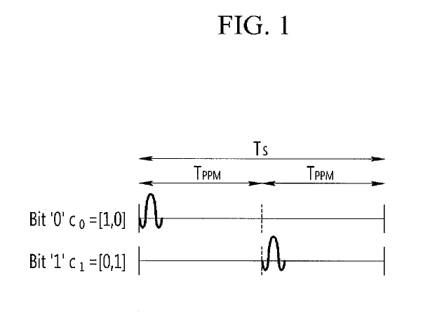

A pulse position modulation (hereinafter, referred to as “PPM”) is the most widely used among the non-coherent modulation methods using the UWB signal. FIG. 1 is a diagram illustrating a typical method of PPM pulse position modulation.

Referring to FIG. 1, the PPM method is a method of dividing one symbol Tₛ into two periods and then mapping a bit 0 into a corresponding symbol when a pulse exists in the front period or mapping a bit 1 when a pulse exists in the rear period.

A general PPM method maps one bit in one symbol period. On the contrary, when one symbol period is divided into a plurality of periods, several bits can be transmitted in one symbol period. For example, when one symbol period is divided into four periods, 2 bits can be transmitted.

Although it has been described as an example that 2-ary PPM dividing the symbol period into two periods is used and the 2-ary PPM is applied to an impulse UWB signal, the present invention is not limited thereto.

In the 2-ary PPM, a signal transmitted during an n-th PPM symbol period can be expressed in Equation 1 as follows.

$${x}^{( n )} ( t ) = {\sum }_{i = 0}^{1} {c}^{( n )} ( i ) w ( t - i \cdot {T}_{PPM} - n \cdot {T}_{s} ) \qquad [ Equation 1 ]$$

Herein, w(t) means a predetermined UWB signal and Tₛ=2T_{PPM} means one symbol period. T_{PPM}, is a PPM period. When bit is 0, the pulse is positioned at a former frame and when bit is 1, the pulse is positioned at later frame.

In addition, c⁽ⁿ⁾=[c⁽ⁿ⁾(0),c⁽ⁿ⁾(1)] is a mapping sequence for pulse positioning with respect to an n-th information bit and c⁽ⁿ⁾=[c⁽ⁿ⁾(0),c⁽ⁿ⁾(1)] is extracted in C={c₀,c₁} which is a sequence set. For example, as shown in FIG. 1, a mapping sequence for bit ‘0’ is c₀=[1,0] and a mapping sequence for bit ‘1’ is c₁=[0,1].

In the above-mentioned PPM method, a method of mapping a bit by grouping N symbols as one unit, not one symbol unit is referred to as a group pulse position modulation (hereinafter, referred to as “GPPM”) method. The GPPM method has a data rate that makes it possible to transmit bits more than N bits, and can increase the amount of information that can be transmitted for the same time, as compared with the PPM method. For example, in the related art, when symbols are grouped in 3-symbol units, a data rate that transmits 3 bits for three symbol periods is achieved.

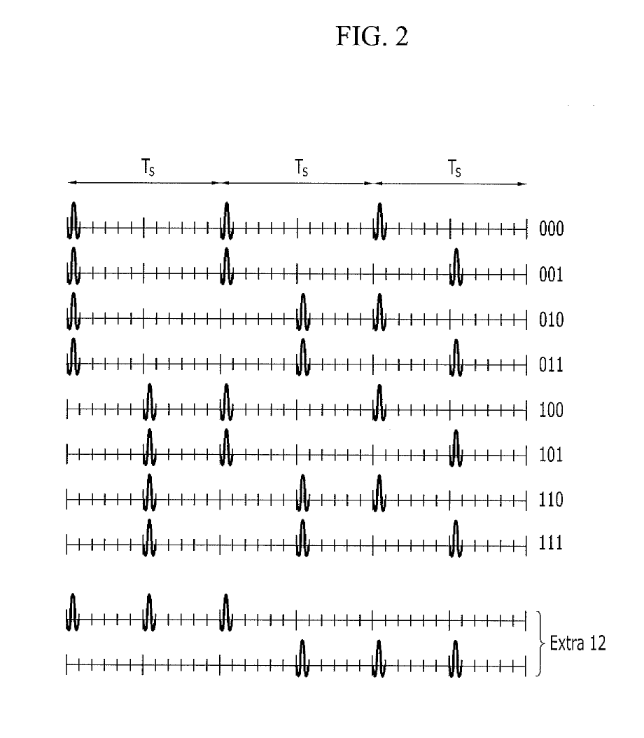

FIG. 2 is a diagram illustrating a method of group pulse position modulation according to an exemplary embodiment of the present invention.

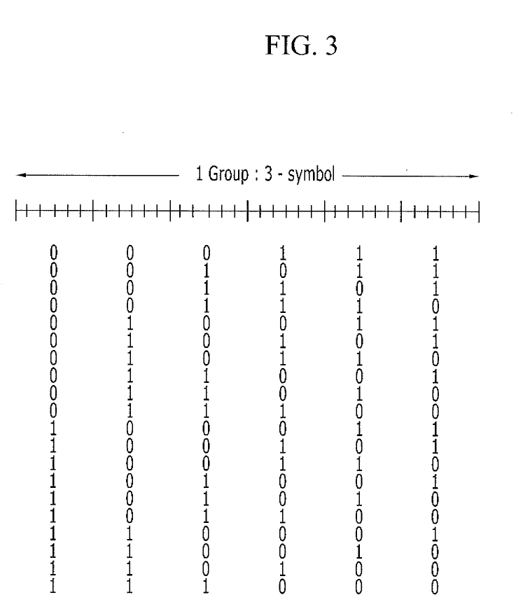

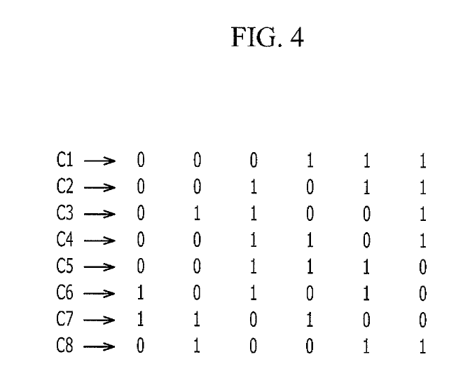

FIG. 3 is a diagram illustrating the number of cases of codeword sets that can be generated in a method of group pulse position modulation according to an exemplary embodiment of the present invention. FIG. 4 is a diagram illustrating a codeword set selected from FIG. 3 to map bits in a method of group pulse position modulation according to an exemplary embodiment of the present invention.

The GPPM method is a method of grouping a plurality of symbols in not one symbol unit but the unit of N symbols as in the PPM method. FIG. 2 illustrates an example of GPPM when N=3 and illustrates a case of grouping a plurality of symbols in the unit of three symbols.

In the related art, 3 bits are transmitted during three symbol periods, while in a combination pulse arrangement in the GPPM method, twelve combinations Extra 12 are provided in addition to the eight combinations (000-111) according to a method of the related art.

That is, twenty combinations are generated when three pulses are necessarily used for a total of six pulse periods. Further, sixteen combinations show 4 bits, such that twenty combinations can transmit the amount of information of more than 4 bits in the time it takes to transmit three symbols.

The number (Pⁿ) of combinations of pulse arrangements that can be generated when the number of groups is generalized as N in the GPPM method can be acquired by the following Equation 2.

$${P}_{N} = ( \begin{matrix}2 \times N \\ N\end{matrix} ) = \frac{2 N \times ( 2 N - 1 ) \times … \times ( N - 1 )}{N \times … \times 2 \times 1} \qquad ( Equation 2 )$$

Herein, N pulses should be in 2N pulse periods.

The GPPM method according to an exemplary embodiment of the present invention can increase the amount of information that can be transmitted, by grouping a plurality of symbols through adopting the plurality of symbols as one unit. Further, the GPPM method can increase the performance of the receiving terminal by being applied to block coding.

In the GPPM method shown in FIG. 2, codeword sets corresponding to twenty combinations are achieved, under a condition that three pulses should exist for six pulse periods. The combination can be expressed by codewords having a length of 6 as show in FIG. 3. That is, FIG. 3 shows a codeword set constituted by codewords that can be generated in the method of group pulse position modulation according to the exemplary embodiment of the present invention shown in FIG. 2.

When eight codewords for mapping 3 bits can be selected from the twenty combinations included in the codeword set, that is, the codewords. In this case, a codeword having an error correction function can be selected. For this, in the exemplary embodiment of the present invention, codewords that are most distant from each other as possible are selected. Specifically, eight codewords are selected from the codewords so that the minimum value of a hamming distance is the largest. The eight selected codewords are shown in FIG. 4. Herein, the hamming distance represents the number of 1s after an XOR (exclusive or) calculation is applied to two codewords between bits.

As such, in the GPPM method, a method of selecting some of the codewords included in the codeword set and mapping the selected codewords to a predetermined bit can be referred to as a block-coded group PPM (so called, BC-GPPM). When N symbols are grouped by generalizing the method, a signal of a k-th group symbol can be expressed in Equation 3 as follows.

$${x}^{( k )} ( t ) = {\sum }_{i = 0}^{2 N - 1} {c}^{( k )} ( i ) \cdot w ( t - i \cdot {T}_{PPM} - k \cdot {NT}_{s} ) \qquad ( Equation 3 )$$

Herein, c^{(k)}=[c^{k)}(0), c^{(k)}(1), . . . , c^{(k)}(2N−1)] is a mapping sequence having a length of 2N for a k-th N-bit group. c^{(k)}=[c^{k)}(0), c^{(k)}(1), . . . , c^{(k)}(2N−1)] is extracted from C={c₀, c₁, . . . , c₂_{^{N}}₋₁} which is the sequence set. Herein, the sequence has a thread of connection with the above-mentioned codeword.

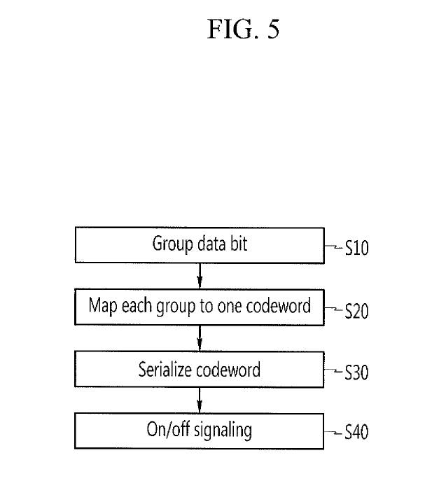

FIG. 5 is a flowchart illustrating a BC-GPPM method according to an exemplary embodiment of the present invention.

In accordance with the BC-GPPM method according to the exemplary embodiment of the present invention, as shown in FIG. 5, first, a transmitter generates a group symbol by grouping binary data in the unit of N bits so as to divide one group symbol period into a plurality of periods and transmit N bits to one group symbol period (S10).

In addition, each of the symbols grouped in the N-bit unit is converted to a predetermined sequence. For example, a sequence having a length of 2N, that is, a codeword is mapped with respect to each grouped symbol (S20).

The codeword which is the subsequent is converted to signal positions of a predetermined number. That is, the mapped codeword is serialized (S30) and on the basis of the codeword, a modulated signal is outputted by on-off signaling the UWB signal at an interval of T_{PPM} (S40). If N=1 herein, the signal modulated in the same manner as the existing PPM may be outputted.

Next, in order to convert the symbols grouped in the N-bit unit to a predetermined sequence, a method of selecting a codeword set constituted by 2^{N} codewords at the time of mapping N bits if the number of groups is N will be described in more detail.

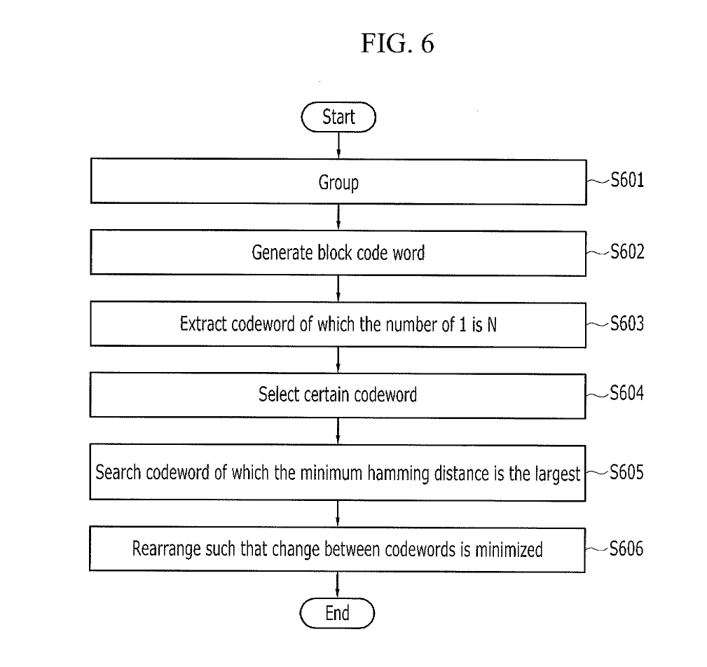

FIG. 6 is a flowchart illustrating a process of extracting a codeword set in a BC-GPPM method according to an exemplary embodiment of the preset invention.

Referring to FIG. 6, a transmitter using the BC-GPPM method according to an exemplary embodiment of the present invention groups a payload data bit stream transmitted from the outside by N bits (S601) and generates a block codeword set constituted by codewords according to combinations of pulse arrangements that can be generated by the grouping (S602). Herein, the block codeword set has a shape of a 2N bit vector space composed of {0, 1} having a length of 2N and includes codewords of total 2^{2N}.

The transmitter extracts candidate codewords of which the number of 1s is N from the block codeword set (S603). Herein, the number of candidate codewords extracted is P_{N} which is the number of combinations that can be generated on the basis of Equation 2. The candidate codewords including the P_{N} candidate codewords are called as “a candidate codeword set” for convenience of description.

The transmitter selects a certain codeword from the candidate codeword set constituted by P_{N} candidate codewords (S604). Next, the transmitter extracts 2^{N} codewords on the basis of the certain codeword from the candidate codeword set. Specifically, the transmitter extracts 2^{N} codewords that maximize dₘᵢₙ from the selected codeword in the candidate codeword set (S605). Herein, the dₘᵢₙ is the minimum hamming distance between different codewords. For example, when 2^{N} codewords are extracted from the candidate codewords as many as P_{N} which is the number of the combinations, 2^{N} codewords are not randomly extracted but 2^{N} codewords are extracted such that the minimum hamming distance between different codewords becomes the largest to provide the ability of error detection and correction. The transmitter rearranges the extracted 2^{N} codewords such that the hamming distance between adjacent candidate codewords is the smallest (S606). The rearranged 2N candidate codewords are a sequence mapping N bits, that is, C={c₀, c₁, . . . , c₂_{^{N}}₋₁} in the BC-GPPM method according to the exemplary embodiment of the present invention. This sequence set including the rearranged 2^{N} candidate codewords may be called as “a final candidate code set” or “a sequence set”.

The BC-GPPM method according to the exemplary embodiment of the present invention gray-maps the groups of data bit streams by N bits, and then maps them to one codeword of the 2^{N} candidate codewords rearranged by the above-mentioned process. At this time, the gray-mapping is a mapping method performed in a common wireless communication system, which minimizes changes between groups or bits.

The BC-GPPM method at N=3 is described in the above embodiment and in accordance with the BC-GPPM method according to the exemplary embodiment of the present invention, candidate codeword sets generated if N=4, N=5, and N=6 are shown in the following table.

TABLE 1
Candidate codeword set at N = 4

| | Symbol | |
|---|---|---|
| Symbol | (Binary) | Codeword |
| (Decimal) | b0, b1, b2, b3 | c0, c1, . . . , c7 |
| 0 | 0000 | 00001111 |
| 1 | 0001 | 00010111 |
| 2 | 0010 | 00011011 |
| 3 | 0011 | 00110011 |
| 4 | 0100 | 01100110 |
| 5 | 0101 | 01010101 |
| 6 | 0110 | 01011010 |
| 7 | 0111 | 00111100 |
| 8 | 1000 | 11110000 |
| 9 | 1001 | 11001100 |
| 10 | 1010 | 10101010 |
| 11 | 1011 | 11000011 |
| 12 | 1100 | 01101001 |
| 13 | 1101 | 10011001 |
| 14 | 1110 | 10100101 |
| 15 | 1111 | 10010110 |

TABLE 2
Candidate codeword set at N = 5

| | Symbol | |
|---|---|---|
| Symbol | (Binary) | Codeword |
| (Decimal) | b0, b1. . . , b4 | c0, c1, . . . , c9 |
| 0 | 00000 | 0000011111 |
| 1 | 00001 | 0000101111 |
| 2 | 00010 | 0000111101 |
| 3 | 00011 | 0010101101 |
| 4 | 00100 | 0011100011 |
| 5 | 00101 | 0100100111 |
| 6 | 00110 | 0001110101 |
| 7 | 00111 | 0000110111 |
| 8 | 01000 | 1101010001 |
| 9 | 01001 | 0101001011 |
| 10 | 01010 | 0011001110 |
| 11 | 01011 | 1110001010 |
| 12 | 01100 | 0001111010 |
| 13 | 01101 | 0000111011 |
| 14 | 01110 | 0101101100 |
| 15 | 01111 | 0100111001 |
| 16 | 10000 | 0000111110 |
| 17 | 10001 | 1100001101 |
| 18 | 10010 | 1100110010 |
| 19 | 10011 | 1110100001 |
| 20 | 10100 | 1000101011 |
| 21 | 10101 | 1011101000 |
| 22 | 10110 | 1011010010 |
| 23 | 10111 | 1001011100 |
| 24 | 11000 | 0011011001 |
| 25 | 11001 | 0110010011 |
| 26 | 11010 | 0110011100 |
| 27 | 11011 | 0101010110 |
| 28 | 11100 | 1001000111 |
| 29 | 11101 | 0111000101 |
| 30 | 11110 | 1010110100 |
| 31 | 11111 | 0111110000 |

TABLE 3
Candidate codeword set at N = 6

| | Symbol | |
|---|---|---|
| Symbol | (Binary) | Codeword |
| (Decimal) | b0, b1. . . , b5 | c0, c1, . . . , c11 |
| 0 | 000000 | 000000111111 |
| 1 | 000001 | 000011011011 |
| 2 | 000010 | 000011101101 |
| 3 | 000011 | 000111000111 |
| 4 | 000100 | 001001010111 |
| 5 | 000101 | 011001110100 |
| 6 | 000110 | 000111111000 |
| 7 | 000111 | 000011110110 |
| 8 | 001000 | 000110011110 |
| 9 | 001001 | 000110110011 |
| 10 | 001010 | 001100011011 |
| 11 | 001011 | 101010010011 |
| 12 | 001100 | 011001001011 |
| 13 | 001101 | 000101101011 |
| 14 | 001110 | 110100011001 |
| 15 | 001111 | 000101011101 |
| 16 | 010000 | 010001011110 |
| 17 | 010001 | 010101101100 |
| 18 | 010010 | 001111010001 |
| 19 | 010011 | 001111100100 |
| 20 | 010100 | 001011011100 |
| 21 | 010101 | 001111001010 |
| 22 | 010110 | 001110101001 |
| 23 | 010111 | 001011100011 |
| 24 | 011000 | 011110001100 |
| 25 | 011001 | 001010001111 |
| 26 | 011010 | 001001111001 |
| 27 | 011011 | 001001101110 |
| 28 | 011100 | 001010111010 |
| 29 | 011101 | 001100110110 |
| 30 | 011110 | 001010110101 |
| 31 | 011111 | 101100100101 |
| 32 | 100000 | 100110001011 |
| 33 | 100001 | 100101011010 |
| 34 | 100010 | 100100101110 |
| 35 | 100011 | 100011101010 |
| 36 | 100100 | 100001001111 |
| 37 | 100101 | 100001111100 |
| 38 | 100110 | 100100010111 |
| 39 | 100111 | 100010011101 |
| 40 | 101000 | 011011000101 |
| 41 | 101001 | 011011101000 |
| 42 | 101010 | 011101000110 |
| 43 | 101011 | 011101011000 |
| 44 | 101100 | 100001110011 |
| 45 | 101101 | 011110110000 |
| 46 | 101110 | 011101100001 |
| 47 | 101111 | 011110000011 |
| 48 | 110000 | 010001100111 |
| 49 | 110001 | 110010100110 |
| 50 | 110010 | 010010101011 |
| 51 | 110011 | 010010010111 |
| 52 | 110100 | 010100001111 |
| 53 | 110101 | 010100110101 |
| 54 | 110110 | 010010111100 |
| 55 | 110111 | 010011110001 |
| 56 | 111000 | 011000011101 |
| 57 | 111001 | 011000110011 |
| 58 | 111010 | 010111100010 |
| 59 | 111011 | 011011010010 |
| 60 | 111100 | 010100111010 |
| 61 | 111101 | 010101010011 |
| 62 | 111110 | 010111010100 |
| 63 | 111111 | 010111001001 |

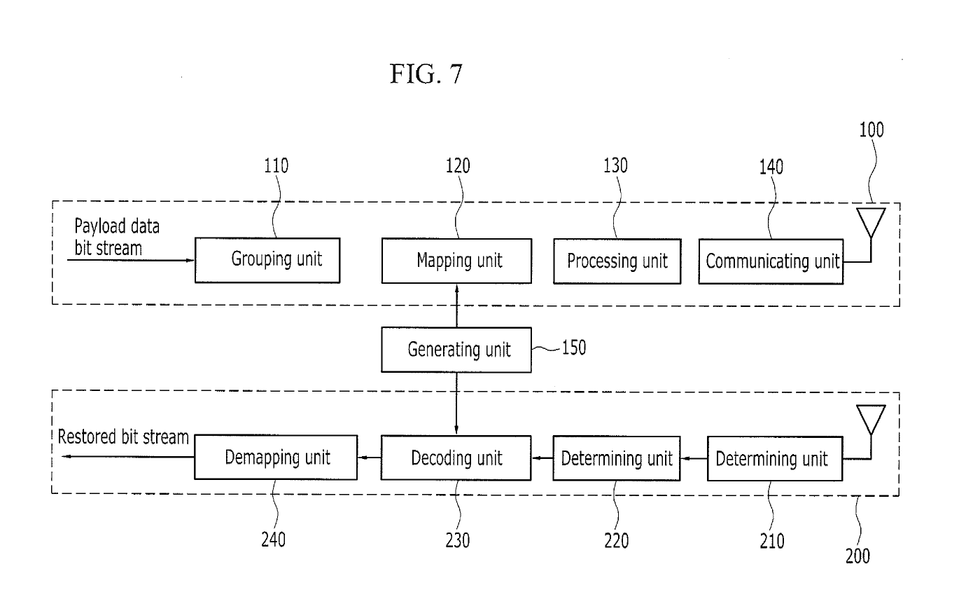

Next, a transmitter and a receiver using a method of block code-based group modulation are described in detail with reference to FIG. 7.

FIG. 7 is a block diagram illustrating a transmitter and a receiver according to an exemplary embodiment of the present invention.

Referring to FIG. 7, a transmitter 100 includes a grouping unit 110, a mapping unit 120, a processing unit 130, and a communicating unit 140, and a receiver 200 includes a detecting unit 210, a determining unit 220, a decoding unit 230, and a demapping unit 240. Further, each of the transmitter 100 and the receiver 200 may further include a generating unit 150 that generates codeword sets. The generating unit 150 according to the exemplary embodiment of the present invention is shown as one component outside the transmitter 100 and the receiver 200, but may be included in the transmitter 100 and the receiver 200.

A payload data bit stream where actual information is included is inputted to the transmitter 100.

The grouping unit 110 groups the inputted payload data bit stream input in N bits and generates symbols by gray-mapping the N-bit grouped results.

The generating unit 150 generates a candidate codeword set including candidate codewords corresponding to P_{N} which is the number of combinations of pulse arrangements that can be generated by N-bit grouping from a block codeword set including 2^{2N} codewords. The generating unit 150 selects 2^{N} candidate codewords from the candidate codeword set and rearranges them to generate the final candidate codeword set. In this case, the generating unit 150 generates the final candidate codeword set by rearranging 2^{N} candidate codewords so that the hamming distance between adjacent codewords are the smallest.

The mapping unit 120 block-maps each group of symbols to one codeword of the codewords included in the final candidate codeword set to convert the corresponding symbol to a predetermined sequence. As such, the mapping unit 120 selects the codeword, that is, the predetermined sequence from the final candidate codeword set which is a set of sequences having a length extending to a certain number of times of the grouped result and converts the selected predetermined sequence to a certain number of signal positions, in order to include the ability of error detection and correction. Herein, the sequence set is a set having elements of sequences that are determined on the basis of the number of periods where the actual signals are transmitted, in the number of predetermined periods where signals may exist.

The processing unit 130 generates a signal by shaping pulses corresponding to a predetermined converted sequence.

The communicating unit 140 transmits the signal generated by the processing unit 130 to the receiver 200 using a radio channel.

Meanwhile, the receiver 200 restores a payload data bit stream from the signal received from the transmitter 100 by wireless communication.

In detail, the detecting unit 210 detects pulse energy from the pulse period included in the signal received from the transmitter 100.

The determining unit 220 performs bit determination with respect to the pulse energy detected in each pulse period. The determination method may be a hard decision that is a first determination method and a soft decision that is a second determination method.

The first determination method (hard decision) determines 1 when the value of the pulse energy obtained in each pulse period is larger that a predetermined threshold value, or determines 0 when the value is the same as or smaller than the threshold value. Alternatively, the method determines 1 for the maximum N+1 energy values, and 0 for the other energy values, by sorting the 2N energy values obtained from one group. That is, the first determination method uses a condition that N pulses should be in one group.

The second determination method (soft decision) quantizes the pulse energy value without determining the pulse energy value to a value of {0, 1}.

In the case in which the result of 2N determined according to the first determination method or the second determination method from the output generated by detection of the pulse energy is z={z(0), z(1), . . . z(2N−1)}, a codeword corresponding to a signal received through the decoding unit 230 can be found.

Since the transmitting unit, that is, the transmitter already knows the sequence set C={c₀, c₁, . . . , c₂_{^{N}}₋1} and knows information that one predetermined codeword is transmitted in the sequence set, the decoding unit 230 acquires correlation values by performing correlation between z which is a result of the determining unit 220 and 2^{N} candidate codewords. In addition, the decoding unit 230 selects a codeword having the maximum correlation value from the acquired correlation values as the transmitted codeword. The selected codeword can be expressed as shown in Equation 4.

$${CM}_{j} = {\sum }_{i = 0}^{2 N - 1} ( 2 {c}_{j} ( i ) - 1 ) \cdot z ( i ) , \\ j = 0 , 1 , … , {2}^{N} - 1 \qquad ( Equation 4 )$$

Herein, cⱼ(i) represents an i-th binary value of a j-th codeword. Therefore, if cⱼ(i)=1, a weighting factor 2cⱼ(i)−1 is 0 and if cⱼ(i)=0, the weighting factor 2cⱼ(i)−1 is −1. As a result, the weighting factor is arranged with signal elements of z, such that a correlation value of an actually transmitted codeword has the largest value.

The decoding unit 220 multiplies all codewords included in the final candidate codeword set having a length of 2N by 2N pulse energy values and selects a code having the maximum value from them. Herein, 1 showing the portion with a pulse is multiplied by an addition point which is a positive weighting factor and 0 is multiplied by the portion without a pulse is multiplied by a subtraction point which is a negative weighting factor.

The demapping unit 240 performs block demapping by using the codeword found through this process to restore a bit stream transmitted from the reception signal. That is, the demapping unit 240 demaps the result of the determining unit 220 by using the found codeword and restores the payload data bit stream by gray-demapping the block-demapped result.

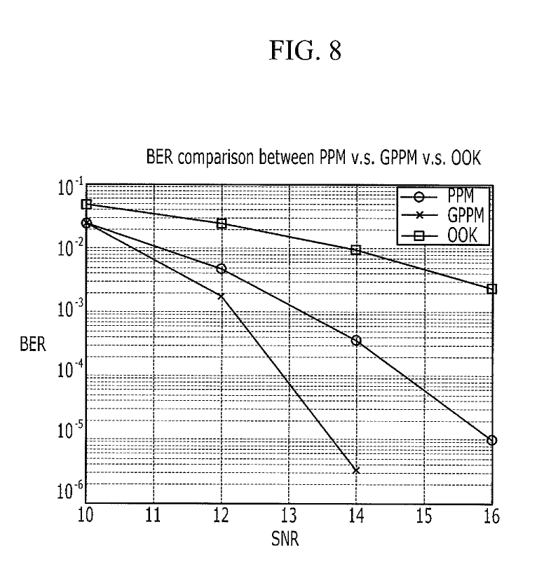

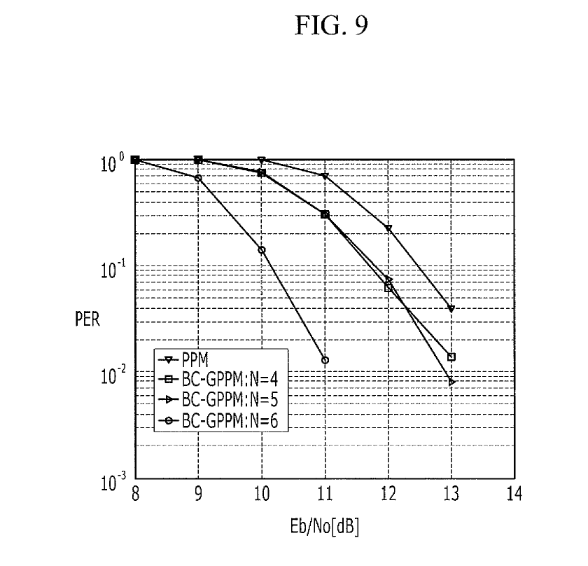

Next, comparison of performance of the PPM method, the GPPM method, and the OOK (On/Off Keying) modulation method in the transmitter and the receiver is described in detail with reference to FIGS. 8 and 9.

FIG. 8 is a diagram comparing the performance of a PPM method, a block coded GPPM method according to an exemplary embodiment of the present invention, and an OOK modulation method in a transmitter and a receiver according to an exemplary embodiment of the present invention.

First, the number of groups used for comparing the PPM method of the related art with the block coded GPPM method is 6.

Referring to FIG. 8, the block coded GPPM method has the same throughput as the PPM method of the related art, and the BER performance is increases by 2 dB at 10̂−4.

The throughput was decreased to achieve the channel coding effect in the related art, but the BC-GPPM method according to the exemplary embodiment of the present invention can provide a channel coding gain without decreasing the entire data rate, by using block coding for the effect of increasing the amount of information generated.

Further, in comparison of the PPM method, the GPPM method, and the OOK (On/Off Keying) modulation method, the performance of the OOK modulation method is lesser than the performance of the PPM method of the related art and the performance of the block coded GPPM method, which is because there is no channel coding effect and the determination performance is deteriorated as compared with the PPM method.

FIG. 9 is a diagram comparing the packet error rate (PER) performance of a BC-GPPM according to an exemplary embodiment of the present invention with the PER performance of a PPM in the related art. Herein, in the case of groups of N bit units used herein, N=4, 5, and 6, a simulation environment is assumed when a payload of a packet is 255 bytes, and an AWGN channel is used.

Referring to FIG. 9, as shown in FIG. 8, the BC-GPPM method according to the exemplary embodiment of the present invention has the same throughput as the PPM of the related art, in particular, the PER performance of the BC-GPPM based on a group of 6-bit unit increases by 2 dB or more at 10̂−1.

The BC-GPPM method according to the exemplary embodiment of the present invention can be applied to cases other than the GPPM method that has to have N pulses, when grouping a plurality of symbols in N symbol units.

In FIG. 3, twenty combinations of codeword sets were acquired under a condition that three pulses are needed when three symbols are grouped. When the condition that three pulses are needed is removed, the entire codeword sets increase to 2⁶ (64) combinations. Herein, the method of group modulation according to another exemplary embodiment of the present invention selects a candidate codeword set constituted by eight codewords for mapping 3 bits. In the method of selecting a codeword, the step of S503 in the method of group modulation illustrated in FIG. 6, that is, the process of extracting a candidate codeword of P_{N} which is the number of combinations is removed. There may be no pulse in the grouped symbol periods if the number of pulses, i.e., the number of 1, is not limited, or pulses may be positioned throughout 2N pulse periods.

According to an exemplary embodiment of the present invention, a transmitter using a method of block code-based group modulation can correct errors while having the same data rate as before grouping bits.

Further, according to an exemplary embodiment of the present invention, a receiver using a method of block code-based group modulation can increase the possibility of accurately restoring signals received from a transmitter.

The above-mentioned exemplary embodiments of the present invention are not embodied only by an apparatus and method. Alternatively, the above-mentioned exemplary embodiments may be embodied by a program performing functions that correspond to the configuration of the exemplary embodiments of the present invention, or a recording medium on which the program is recorded. These embodiments can be easily devised from the description of the above-mentioned exemplary embodiments by those skilled in the art to which the present invention pertains.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of group modulation of data, comprising:
in a method of data modulation,
generating symbols by grouping an input data bit stream into N-bit groups;
converting the symbols generated by the grouping to predetermined sequences; and
converting the sequences to signal positions of a predetermined number.

2. The method of group modulation of claim 1, wherein the converting to the sequences maps one sequence from a set of sequences having a length extending a certain number of times of the number of data bits constituting the group to the symbol generated by the grouping.

3. The method of group modulation of claim 2, wherein the sequence set is generated based on the number of periods in which a signal is actually transmitted in the number of periods in which a predetermined signal is existable.

4. The method of group modulation of claim 1, wherein in the converting to the signal position, the number of signal periods in which transmission power is applied is limited to a predetermined number within a predetermined time period and there is not limit in a combination of time positions in which the transmission power is applied within the predetermined time period.

5. A method of group modulation, comprising:
generating symbols by grouping a data bit stream into N-bit groups;
generating a block codeword set constituted by a plurality of codewords while corresponds to the result of grouping to the predetermined number;
selecting candidate codewords of a predetermined number on the basis of the block codeword set;
generating a final candidate codeword set by rearranging the selected candidate codewords; and
block-mapping each of the groups constituting the symbols to one of the rearranged candidate codewords of the final candidate codeword set.

6. The method of claim 5, wherein the predetermined number is 2^{N}.

7. The method of claim 5, wherein the generating a final candidate codeword set rearranges the selected candidate codewords so that a hamming distance between adjacent candidate codewords is the smallest.

8. The method of claim 5, wherein the selecting candidate codewords of a predetermined number includes:
generating a candidate codeword set constituted by candidate codewords corresponding to combinations of pulse arrangements generated through the result of grouping to the predetermined number from the block codeword set; and
selecting candidate codewords of a predetermined number of the candidate codeword set.

9. The method of claim 8, wherein the selecting candidate codewords includes:
selecting a predetermined codeword from the candidate codeword set; and
extracting two or more candidate codewords so that a value having a minimum hamming distance from the predetermined code selected from the selected codeword becomes the largest.

10. The method of claim 5, wherein the generating the symbols generates the symbols by gray-mapping bits of each of the groups.

11. The method of claim 5, wherein the block-mapping converts the symbol to a predetermined sequence by block-mapping the symbol to the candidate codeword of the final codeword set and the predetermined sequence is a sequence constituted by a set of sequences having a length extending a certain number of times of the number of data bit streams grouped to the predetermined number.

12. A transmitter using a method of block code-based group modulation, comprising:
a grouping unit that generates symbols by grouping a data bit stream into N-bit groups;
a generating unit that generates a codeword set composed of codewords corresponding to combinations of arrangements of pulses that are generated by the result of grouping to the predetermined number and generates a final candidate codeword set including 2^{N} candidate codewords in the codeword set; and
a mapping unit that block-maps each of the groups constituting the symbols to one of the codewords of the final candidate codeword set.

13. The transmitter of claim 12, wherein the grouping unit generates the symbol by gray-mapping a bit of each group.

14. The transmitter of claim 12, wherein the generating unit selects 2^{N} candidate codewords from the codeword set and rearranges the selected candidate codewords so that a hamming distance between adjacent candidate codewords is the smallest to generate the final candidate codeword set.

15. The transmitter of claim 14, wherein the mapping unit selects a predetermined codeword from the codeword set and finds codewords that maximize the minimum hamming distance from the selected codeword to select the 2^{N} candidate codewords.

16. The transmitter of claim 12, wherein the mapping unit converts the symbols to a predetermined sequence by block-mapping the symbol to the candidate codeword of the final codeword set and the predetermined sequence is selected from a set of sequences having a length extending a certain number of times of the grouped data bits.

17. The transmitter of claim 16, further comprising a processing unit which generates the symbol by shaping a pulse corresponding to the predetermined sequence and transmits the generated signal to the outside, using a wireless channel.
